(19) United States
(12) Patent Application Publication
(10) Pub. No.: US 2022/0130751 A1
(43) Pub. Date: Apr. 28, 2022

(54) COPPER PLATING STRUCTURE AND PACKAGE STRUCTURE INCLUDING THE SAME

(71) Applicant: Industrial Technology Research Institute, Hsinchu (TW)

(72) Inventors: Ming-Huei Yen, Taipei City (TW); Wen-Jin Li, Taipei City (TW); Zi-Ting Lin, New Taipei City (TW); Yu-Ling Chang, Chiayi County (TW)

(73) Assignee: Industrial Technology Research Institute, Hsinchu (TW)

(21) Appl. No.: 17/131,771

(22) Filed: Dec. 23, 2020

(30) Foreign Application Priority Data
Oct. 27, 2020 (TW) 109137312

(51) Int. Cl. H01L 23/498; H01L 23/373; B32B 15/01; B32B 15/20

(52) U.S. Cl. CPC H01L 23/49866; B32B 15/20; B32B 15/01; H01L 23/3735

(57) ABSTRACT

A copper plating structure and a package structure including the same are provided, and the copper plating structure includes at least one first copper layer and at least one second copper layer. The first copper layer includes a (111) crystal plane, wherein a proportion of the (111) crystal plane in each of the first copper layers is 36% to 100%. The second copper layer is located on the first copper layer and includes a non-(111) crystal plane or includes a (111) crystal plane and a non-(111) crystal plane, wherein a proportion of the (111) crystal plane in each of the second copper layers is 0% to 57%.

### CROSS-REFERENCE TO RELATED APPLICATION

This application claims the priority benefit of Taiwan application no. 109137312, filed on Oct. 27, 2020. The entirety of the above-mentioned patent application is hereby incorporated by reference herein and made a part of this specification.

### TECHNICAL FIELD

The disclosure relates to a copper plating structure and a package structure including the same.

### BACKGROUND

In response to requirements for the heat dissipation and high current and voltage loads of power devices, the thickness of copper wires is thicker (such as greater than 300 μm), and circuit cross-sections are also expected to remain square to meet the requirements of heat dissipation and high current and voltage loads. Therefore, a current subtractive method may not meet the requirements of the power devices because the circuit cross-section may not be maintained in a square shape.

As for a semi-additive method, although the cross-sectional shape of the circuit may be maintained, increase in the thickness of copper wires causes stress accumulation, thus easily causing issues such as plate bending and even plating peeling, making it difficult to exceed 200 μm in thickness.

Although low-speed electroplating has the opportunity to solve the above issues, because the current density for electroplating is too low, the process time is too long, so that the process cost is not economical.

### SUMMARY

The disclosure provides a copper plating structure that may eliminate the overall deformation and residual stress of the copper plating structure.

The disclosure further provides a package circuit structure having the copper plating structure above.

The disclosure further provides a package heat dissipation structure having the copper plating structure above.

The copper plating structure of the disclosure includes at least one first copper layer and at least one second copper layer. The first copper layer includes a (111) crystal plane, wherein a proportion of the (111) crystal plane in each of the first copper layers is 36% to 100%. The second copper layer is located on the first copper layer and includes a non-(111) crystal plane or includes a (111) crystal plane and a non-(111) crystal plane, wherein a proportion of the (111) crystal plane in each of the second copper layers is 0% to 57%.

The package circuit structure of the disclosure includes the copper plating structure above and is formed at at least a side of a substrate.

The package heat dissipation structure of the disclosure includes the copper plating structure above and is formed at at least a side of a substrate.

Based on the above, in the disclosure, via the special design of the plating structure, in addition to maintaining the deposition rate of the coating, the accumulation of stress or deformation caused by the increase in thickness may also be further eliminated, thus overcoming the limitations of the traditional manufacturing process.

Several exemplary embodiments accompanied with figures are described in detail below to further describe the disclosure in details.

### BRIEF DESCRIPTION OF THE DRAWINGS

The accompanying drawings are included to provide further understanding, and are incorporated in and constitute a part of this specification. The drawings illustrate exemplary embodiments and, together with the description, serve to explain the principles of the disclosure.

FIG. 1 is a cross-sectional view of a copper plating structure according to an embodiment of the disclosure.

FIG. 2 is a cross-sectional view of a copper plating structure according to another embodiment of the disclosure.

### DETAILED DESCRIPTION OF DISCLOSED EMBODIMENTS

In the following, exemplary embodiments of the disclosure are comprehensively described with reference to figures, but the disclosure may also be implemented in various different forms and should not be construed as limited to the embodiments of the specification. In the figures, for clarity, the size and thickness of each region, portion, and layer do not need to be shown to actual scale. To facilitate understanding, the following description adopts reference numerals to describe the same components.

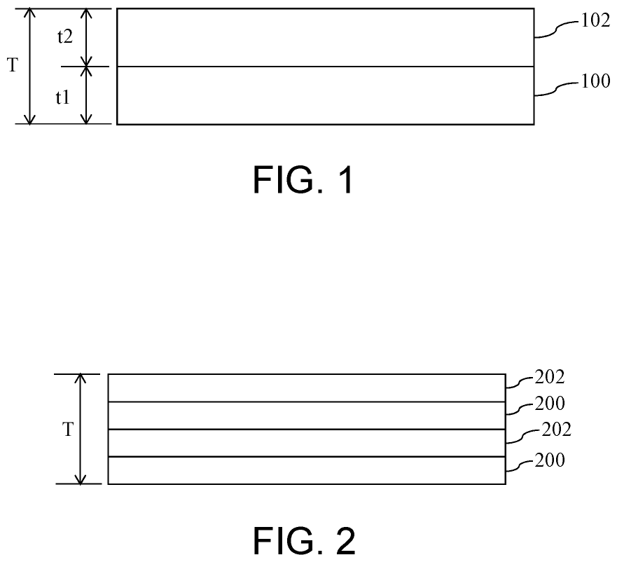

FIG. 1 is a cross-sectional view of a copper plating structure according to an embodiment of the disclosure.

Please refer to FIG. 1, the copper plating structure of the present embodiment includes a first copper layer 100 and a second copper layer 102. The first copper layer 100 includes a (111) crystal plane, wherein the proportion of the (111) crystal plane in each of the first copper layers is 36% to 100%. In other words, the first copper layer 100 may also include a non-(111) crystal plane, and the same layer includes a plurality of crystal planes. Therefore, the “proportion” of a crystal plane refers to the percentage value obtained by dividing the area occupied by a specific crystal plane in the crystal plane of the copper layer (surface) by the surface area of the copper layer, wherein the non-(111) crystal plane may be a (200) crystal plane, a (220) crystal plane, or a (311) crystal plane. The second copper layer 102 is located on the first copper layer 100 and is preferably in direct contact with the first copper layer 100. The second copper layer 102 includes a non-(111) crystal plane or includes a (111) crystal plane and a non-(111) crystal plane, wherein the proportion of the (111) crystal plane in each of the second copper layers 102 is 0% to 57%, and the non-(111) crystal plane includes a (200) crystal plane, a (220) crystal plane, or a (311) crystal plane. In other words, if the proportion of the (111) crystal plane in the second copper layer 102 is 0, the second copper layer 102 does not include a (111) crystal plane but is composed of a non-(111) crystal plane. Moreover, if the proportion of the (111) crystal plane in the second copper layer 102 is greater than 0, the second copper layer 102 includes both a (111) crystal plane and a non-(111) crystal plane. In an embodiment, the proportion of the (111) crystal plane in the first copper layer 100 is different from the proportion of the (111) crystal plane in the second copper layer 102. Therefore, the residual stresses of the two copper layers may cancel out each other by the difference in the ratio of the (111) crystal plane. For example, the difference between the proportion of the (111) crystal plane in the first copper layer 100 and the proportion of the (111) crystal plane in the second copper layer 102 is 5% or more, so that the residual stress of the first copper layer 100 is compressive stress, and the residual stress of the second copper layer 102 is tensile stress. In another embodiment, if the proportion of the (111) crystal plane in the first copper layer 100 is close to the proportion of the (111) crystal plane in the second copper layer 102, impurities may be added to the first copper layer 100 and/or the second copper layer 102 to make the residual stresses of the two copper layers cancel each other out, such as doping with impurities that may provide the first copper layer 100 with tensile stress; and doping with impurities that may provide the second copper layer 102 with compressive stress.

Please continue to refer to FIG. 1, a thickness t1 of the first copper layer 100 is, for example, 1 μm to 276 μm, a thickness t2 of the second copper layer 102 is, for example, 1 μm to 276 μm, and a total thickness T of the copper plating structure is, for example, 2 μm to 1 mm. In another embodiment, the thickness t1 is 3 μm to 250 μm and the thickness t2 is 3 μm to 250 μm; preferably, the thickness t1 is 5 μm to 200 μm, and the thickness t2 is 5 μm to 200 μm. However, the disclosure is not limited thereto, and the thicknesses (t1, t2) of the above layers may be changed according to the setting of the tolerance value of warpage.

In detail, since the thickness of a single copper layer is not easily measured directly, the thickness of a single copper layer is simulated and calculated according to the following formula (1).

$$σ = \frac{{E}_{s} \times {d}_{s}^{2} \times Δδ}{3 {r}^{2} ( 1 - {V}_{s} ) {d}_{f}} \qquad ( 1 )$$

In formula (1), σ is the stress of a single copper layer, Δδ is the relative height difference from the center of the substrate to the radius r before and after electroplating, r is the radius value of the measurement position on the substrate, dₛ is the thickness of the substrate, d_{f} is the thickness of a single copper layer, Eₛ is the Young's modulus of the substrate, and Vₛ is Poisson's ratio; and if σ is positive, σ is expressed as tensile stress, and if σ is negative, σ is expressed as compressive stress.

In the case that an AlN substrate is used for calculation, the AlN substrate has a thickness of 0.15 mm, a Young's modulus of 330 GPa, and a Passon's ratio of 0.24; the plating stress is set to 7 MPa, and the warpage (tolerance value) is set to 3 mm. The calculated result is that the thickness of the single copper layer is 276 μm. In other words, to maintain the warpage at the tolerable value or less, the thickness of a single copper layer needs to be thinner than 276 μm.

Therefore, the thickness of the copper layer may be changed according to requirements. For example, if the tolerance value of warpage is set lower, the thickness of the single copper layer is naturally thinner; or if the thickness or the material of the substrate is changed, the above value is also changed.

Moreover, the copper plating structure of the disclosure may be completed using an existing process, such as a semi-additive method, so that the cross-sectional shape of the copper plating structure may be maintained as a square. Moreover, increase in the thickness T of the copper plating structure does not cause stress to accumulate, thereby avoiding issues such as plate bending and plating peeling, and the manufacturing cost may also be economically beneficial.

FIG. 2 is a cross-sectional view of a copper plating structure according to another embodiment of the disclosure.

In FIG. 2, the copper plating structure is formed by alternately stacking a plurality of first copper layers 200 and a plurality of second copper layers 202. The positions, sizes, materials, etc. of the first copper layers 200 and the second copper layers 202 are all as provided for the first copper layer and the second copper layer of the previous embodiment, and therefore are not repeated herein. Moreover, although FIG. 2 shows a four-layer structure, it should be understood that the disclosure is not limited thereto, and the number of the first copper layers 200 and the second copper layers 202 may be changed according to requirements.

In the present embodiment, by design, the first copper layers 200 having the preferential orientation of (111) crystal plane and the second copper layers 202 having the preferential orientation of non-(111) crystal plane are alternately stacked to form a lamella-like structure. Therefore, compressive stress and tensile stress cancel each other out to alleviate the deformation and stress of the overall copper plating structure.

Due to the characteristics of low deformation and low residual stress, the copper plating structure of the disclosure is suitable for a package structure such as a package circuit structure or a package heat dissipation structure. For example, the first copper layers 200 having the preferential orientation of (111) crystal plane may be formed at one side (surface) of a substrate, and then the second copper layers 202 having the preferential orientation of non-(111) crystal plane may be formed; and so on. Moreover, if used in a double-sided package structure, a copper plating structure may be formed at both sides (front and back) of the substrate.

Experiments are provided below to verify the efficacy of the disclosure. However, the scope of the disclosure is not limited to the following experiments.

### Comparative Example 1

Electroplating was performed on a substrate using an electroplating solution for 30 minutes to form a first copper layer for which the proportion of the (111) crystal plane was about 49%.

### Comparative Example 2

The process of Comparative example 1 was continued to perform the electroplating for 10 more minutes to increase the thickness of the first copper layer.

### Experimental Example 1

The process of Comparative example 2 was continued, and the plating current density was changed using the same electroplating solution, or electroplating was performed on the first copper layer for 30 minutes using another electroplating solution to form a second copper layer for which the proportion of the (111) crystal plane was about 44%.

### Experimental Example 2

The process of Experimental example 1 was continued to perform the electroplating for 10 more minutes to increase the thickness of the second copper layer.

<Stress Calculation>

According to the ASTM B975 plating stress measurement method (converting the plating stress value with the standard sample opening distance), the opening distances of Comparative example 1, Comparative example 2, Experimental example 1, and Experimental example 2 were measured, and the resulting stress values were respectively −7.41 MPa, −8.65 MPa, −2.66 MPa, −2.31 MPa. That is, as the thickness of the first copper layer was greater, the residual stress was gradually increased, but after the second copper layer was formed, the residual stress was gradually decreased. Therefore, the overlap of platings having compressive stress and tensile stress may alleviate the deformation caused by the platings to reduce the overall residual stress.

Based on the above, in the disclosure, by adjusting the proportion of the (111) crystal plane in the plating structure, a copper layer having compressive stress or tensile stress may be formed. Moreover, by staggering a plurality of copper layers, the effect of increasing the thickness and reducing the stress or deformation of a thick film is achieved, thus overcoming the limitations of the traditional manufacturing process. In addition to maintaining the deposition rate of the coating, the cross-sectional shape of the copper plating structure may also be maintained.

It will be apparent to those skilled in the art that various modifications and variations may be made to the structure of the disclosed embodiments without departing from the scope or spirit of the disclosure. In view of the foregoing, it is intended that the disclosure cover modifications and variations of this disclosure provided they fall within the scope of the following claims and their equivalents.

What is claimed is:

1. A copper plating structure, comprising:
at least one first copper layer comprising a (111) crystal plane; and
at least one second copper layer comprising a non-(111) crystal plane or comprising a (111) crystal plane and a non-(111) crystal plane, wherein the at least one second copper layer is located on the first copper layer,
wherein a proportion of the (111) crystal plane in each of the first copper layers is 36% to 100%, and a proportion of the (111) crystal plane in each of the second copper layers is 0% to 57%.

2. The copper plating structure of claim 1, wherein a difference between the proportion of the (111) crystal plane in the first copper layer and the proportion of the (111) crystal plane in the second copper layer is 5% or more.

3. The copper plating structure of claim 1, wherein a thickness of each of the first copper layers is 1 μm to 276 μm.

4. The copper plating structure of claim 1, wherein a thickness of each of the second copper layers is 1 μm to 276 μm.

5. The copper plating structure of claim 1, wherein a total thickness of the copper plating structure is 2 μm to 1 mm.

6. The copper plating structure of claim 5, wherein a number of the first copper layer is a plurality, a number of the second copper layer is a plurality, and the plurality of first copper layers and the plurality of second copper layers are alternately stacked.

7. The copper plating structure of claim 1, wherein the non-(111) crystal plane comprises a (200) crystal plane, a (220) crystal plane, or a (311) crystal plane.

8. A package circuit structure, comprising the copper plating structure of claim 1, formed at at least a side of a substrate.

9. A package heat dissipation structure, comprising the copper plating structure of claim 1, formed at at least a side of a substrate.

10. A package circuit structure, comprising the copper plating structure of claim 2, formed at at least a side of a substrate.

11. A package heat dissipation structure, comprising the copper plating structure of claim 2, formed at at least a side of a substrate.

12. A package circuit structure, comprising the copper plating structure of claim 3, formed at at least a side of a substrate.

13. A package heat dissipation structure, comprising the copper plating structure of claim 3, formed at at least a side of a substrate.

14. A package circuit structure, comprising the copper plating structure of claim 4, formed at at least a side of a substrate.

15. A package heat dissipation structure, comprising the copper plating structure of claim 4, formed at at least a side of a substrate.

16. A package circuit structure, comprising the copper plating structure of claim 5, formed at at least a side of a substrate.

17. A package heat dissipation structure, comprising the copper plating structure of claim 5, formed at at least a side of a substrate.

18. A package circuit structure, comprising the copper plating structure of claim 6, formed at at least a side of a substrate.

19. A package heat dissipation structure, comprising the copper plating structure of claim 6, formed at at least a side of a substrate.

20. A package circuit structure, comprising the copper plating structure of claim 7, formed at at least a side of a substrate.
